(19) United States
(12) Patent Application Publication
(10) Pub. No.: US 2024/0332245 A1
(43) Pub. Date: Oct. 3, 2024

(54) DEVICE AND METHOD FOR BONDING SEMICONDUCTOR CHIP

(71) Applicant: Samsung Electronics Co., Ltd., Suwon-si (KR)

(72) Inventors: Dae Seo PARK, Suwon-si (KR); Woon Chun KIM, Suwon-si (KR)

(73) Assignee: Samsung Electronics Co., Ltd., Suwon-si (KR)

(21) Appl. No.: 18/610,924

(22) Filed: Mar. 20, 2024

(30) Foreign Application Priority Data
Mar. 30, 2023 (KR) 10-2023-0042289

(51) Int. Cl. H01L 23/00

(52) U.S. Cl. CPC H01L 24/75; H01L 24/81; H01L 24/83; H01L 24/92; H01L 2224/751; H01L 2224/75301; H01L 2224/7555; H01L 2224/81203; H01L 2224/83203; H01L 2224/9211

(57) ABSTRACT

The present disclosure relates to a semiconductor chip bonding device and a semiconductor chip bonding method using the same, the semiconductor chip bonding device bonds semiconductor chips on a substrate, and includes a bonding head disposed on the semiconductor chip; a substrate support disposed below the substrate; a dam member for surrounding an edge of the bonding head and contacting an upper side of the substrate; and a gas blower spaced and disposed on the substrate support, disposed between the bonding head and the dam member, and supplying gas to the substrate direction.

### CROSS-REFERENCE TO RELATED APPLICATION

This application claims priority to and the benefit of Korean Patent Application No. 10-2023-0042289 filed in the Korean Intellectual Property Office on Mar. 30, 2023, the entire contents of which are incorporated herein by reference.

### BACKGROUND

### Field

The present disclosure relates to semiconductor packages. More particularly, the present disclosure relates to a semiconductor chip bonding device and a semiconductor chip bonding method.

### Description of the Related Art

In a process for manufacturing a semiconductor package, a process for bonding a substrate and a semiconductor chip and/or bonding stacked semiconductor chips is used. For example, a pad of a semiconductor chip may be bonded to a pad of a wafer by a thermal compression bonding process by using a solder and a non-conductive film (NCF) in a chip on wafer (CoW) process.

In this instance, when the thermal compression bonding process is performed, a non-conductive film filet may excessively leak to an outside from a center of an edge of the semiconductor chip, and therefore the non-conductive film filet is insufficiently filled in the corner of the semiconductor chip, and voids are generated.

In these instances, a warpage of the semiconductor package may be generated by a difference of heat expansion coefficients (CTE) between the leaked non-conductive film filet and a molding material. Cracks may be generated near the leaked non-conductive film filet when a wafer level package is sawed into individual packages. For example, the molding material may be input to the voids generated in the corner region of the semiconductor chip to be cracked and peeled off.

### SUMMARY

The present disclosure has been made in an effort to provide a semiconductor chip bonding device for reducing, mitigating, and/or preventing a semiconductor package from warping, reducing, mitigating, and/or preventing the same from being cracked when the semiconductor package is incised, and reducing, mitigating, and/or preventing a corner region of the semiconductor chip from peeling off by voids.

The present disclosure has been made in another effort to provide a method for bonding a semiconductor chip using a semiconductor chip bonding device having the above-described advantages.

At least one embodiment of the present disclosure provides a device configured to bond a semiconductor chip on a substrate, the device comprising: a bonding head configured to be on the semiconductor chip; a substrate support configured to support the substrate; a dam member configured to surround an edge of the bonding head and to contact an upper side of the substrate; and a gas blower configured to be spaced apart from and over the substrate support, to be between the bonding head and the dam member, and to supply gas towards the substrate.

One side of the gas control member facing the semiconductor chip may have a slant, and the one side may include a curve or a plane. An area of the gas control member in a cross-sectional view may gradually increase when approaching to the substrate.

The gas control member may include a protrusion, and the protrusion may have a slant portion having an angle with respect to the substrate.

The slant portion may have a curved shape or a trapezoidal shape in a plan view. The slant portion may have at least one of straight line or a curve in a cross-sectional view. The dam member may comprise at least one of silicon, fluorine, or a compound thereof.

The bonding head may include a heater portion, and the heater portion may be configured to heat the bonding head to a temperature of 250° C. or more. A temperature of the gas may be in range of 150° C. to 250° C. The substrate support may be configured to heat the substrate to a temperature in a range of 50° C. to 150° C.

The gas blower may be configured to supply an inert gas. The gas blower may include first to fourth spray portions surrounding the bonding head, and the first to fourth spray portions may have a bar shape including a long side and a short side. The first to fourth portions may be configured with a plurality of blowing holes, and the blowing holes may be in a lattice form.

Another embodiment of the present disclosure provides a device configured to bond a semiconductor chip on a substrate and to limit a non-conductive film filet from spreading, the device comprising a bonding head configured to heat-pressurize the semiconductor chip, the bonding head including a heater portion, a collet on a lower side of the heater portion, and a head portion on a lower side of the collet and configured to contact the semiconductor chip; a substrate support configured to support the substrate and to heat the substrate to a temperature range lower than a temperature range of the heater portion; a dam member including a gas control member and a support portion, the gas control member configured to surround the bonding head, to contact an upper side of the substrate, and including a slant portion with an angle with respect to the substrate, and the support portion on the gas control member and configured to fix the gas control member to the substrate; and a gas blower configured to be spaced apart from and over the substrate support, to be between the bonding head and the dam member, and to supply gas of 150° C. or more towards the substrate.

A temperature of the gas may be in a range of 150° C. to 250° C. The heater portion may be configured to heat the head portion to 250° C. or more. The substrate support may be configured to heat the substrate to a temperature in a range of 50° C. to 150° C.

Another embodiment of the present disclosure provides a method for bonding a semiconductor chip including: using a bonding head to position a semiconductor chip on a substrate such that a non-conductive film of the semiconductor chip is between the semiconductor chip and the substrate; positioning a dam member to surround the semiconductor chip such that dam member is spaced apart from an edge of the semiconductor chip and contacts an upper side of the substrate; bonding the semiconductor chip to the substrate by providing heat and pressure to the semiconductor chip; and spraying gas along at least one side of the dam member, the at least one side of the dam member being between the semiconductor chip and the dam member.

The device for bonding a semiconductor chip according to at least one embodiment of the present disclosure includes the dam member and the gas blower configured to control the size of the non-conductive film filet, remove the voids in the corner portion of the semiconductor chip, and reduce, mitigate, and/or prevent the semiconductor package from warping.

The device for bonding a semiconductor chip according to some of the embodiments of the present disclosure includes the above-described merits, reduces, mitigates, and/or prevents generation of cracks after incising the semiconductor package, and reduces, mitigates, and/or prevents the corner region of the semiconductor chip from peeling off because of the voids.

The method for bonding a semiconductor chip according to at least some embodiments of the present disclosure provides the bonding method having the above-noted advantages.

### BRIEF DESCRIPTION OF THE DRAWINGS

FIG. 1A to FIG. 1C show front views of devices for bonding a semiconductor chip according to embodiments of the present disclosure.

FIG. 2A to FIG. 2C show top plan views of devices for bonding a semiconductor chip according to some embodiments of the present disclosure.

FIG. 3A to FIG. 3C show schematic diagrams of movement of gas by dam members of devices for bonding a semiconductor chip according to some embodiments of the present disclosure.

FIG. 4 shows a gas supplying direction and a non-conductive film filet growing direction according to at least one embodiment of the present disclosure.

FIG. 5A to FIG. 5C show a simulation according to influences of a cross-section of dam members according to some embodiments of the present disclosure.

FIG. 6A to FIG. 6C show a simulation according to influences of cross-sections of dam members and a non-conductive film filet according to some embodiments of the present disclosure.

FIG. 7 shows a relationship between a non-conductive film filet and a substrate according to at least one embodiment of the present disclosure.

FIG. 8A to FIG. 8D show a method for bonding a semiconductor chip using a device for bonding a semiconductor chip according to at least one embodiment of the present disclosure.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

Parts that are irrelevant to the description will be omitted to clearly describe the present disclosure, and the same elements will be designated by the same reference numerals throughout the specification. In the drawings, like numerals refer to like elements throughout, therefore the repeated descriptions may be omitted.

The size and thickness of each configuration shown in the drawings are arbitrarily shown for better understanding and ease of description, but the present disclosure is not limited thereto. In the drawings, the thickness of layers, films, panels, regions, etc., are enlarged for clarity. The thicknesses of some layers and areas are exaggerated for convenience of explanation.

It will be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means positioned on or below the object portion, and does not necessarily mean positioned on the upper side of the object portion based on a gravitational direction.

Unless explicitly described to the contrary, the word “comprise”, and variations such as “comprises” or “comprising”, will be understood to imply the inclusion of stated elements but not the exclusion of any other elements. When the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometric. When referring to “C to D”, this means C inclusive to D inclusive unless otherwise specified.

The phrase “in a plan view” means viewing an object portion from the top, and the phrase “in a cross-sectional view” means viewing a cross-section of which the object portion is vertically cut from the side.

Hereinafter, several embodiments of the present disclosure will be described in detail so that those skilled in the art to which the present disclosure pertains may easily practice the present disclosure. However, the present disclosure may be implemented in various different forms and is not limited to embodiments provided herein.

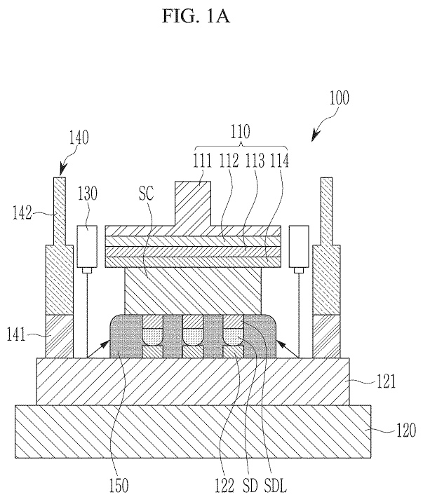

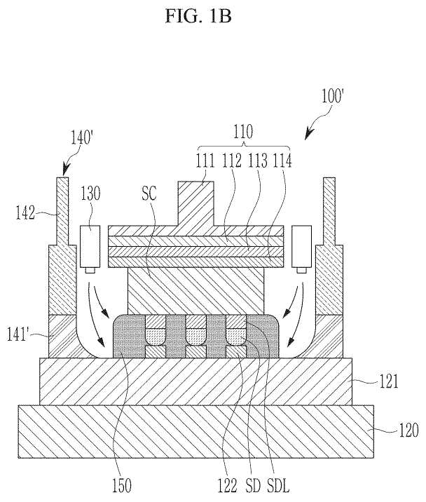

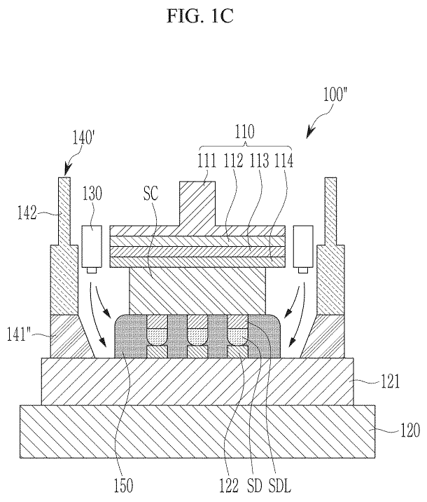

FIG. 1A to FIG. 1C show front views of devices 100, 100′, and 100″ for bonding a semiconductor chip according to some embodiments of the present disclosure.

The semiconductor chip bonding device 100 is configured to bond a semiconductor chip on a substrate and/or to bond stacked semiconductor chips on the substrate in a process for, e.g., producing a high bandwidth memory (HBM). For example, the semiconductor chip bonding device 100 may be used to a process for bonding a multi-chip stack. The semiconductor chip may be bonded to the substrate and/or to another semiconductor chip using the non-conductive film (NCF) and the solder.

For the bonding a multi-chip stack, the non-conductive film filet 150 between the semiconductor chip at a bottom end of the stacked semiconductor chips and the substrate may overflow in a center of an edge of the semiconductor chip, and voids may be generated in the corner portion. For example, without being limited to a specific theory or mechanism, a surface tension of the non-conductive film filet 150, while still in a fluid state, may induce a circular shape in the non-conductive film filet 150 to reduce the free energy at the surface, thereby pulling the non-conductive film filet 150 away from the corner portions of the semiconductor chip. As described in further detail below, the semiconductor chip bonding device 100 may reduce, mitigate, and/or prevent this overflow of the non-conductive film filet 150 between the substrate and the semiconductor chip at the bottom end and the generation of voids for the process for bonding a multi-chip stack.

Referring to FIG. 1A, the semiconductor chip bonding device 100 bonds the semiconductor chip SC on the substrate 121, and includes a bonding head 110, a substrate support 120, a gas blower 130, and a dam member 140. For example, the semiconductor chip bonding device 100 includes a bonding head 110 configured to be disposed on the semiconductor chip, a substrate support 120 configured to be disposed below the substrate 121, a gas blower 130 configured to be spaced apart from and on the substrate support 120 and on an outside of the bonding head 110 to supply gas in a direction of the substrate 121, and a dam member 140 configured to be disposed on an outside of the gas blower 130 and to contact an upper side of the substrate 121 to reduce, mitigate, and/or prevent the non-conductive film filet 150 from spreading.

The bonding head 110 may be configured to heat-pressurize the semiconductor chip SC toward the substrate 121. For example, the bonding head 110 may stack the semiconductor chips SC on the substrate 121 to form a multi-chip stack. The bonding head 110 may, for example, include a main body 111 connected to a driver (not shown) configured to drive the bonding head, a heater portion 112 for heat-pressurizing the semiconductor chip SC, a collet 113 including a thermally conductive member installed on a lower side of the heater portion 112, and a head portion 114 dispose on a lower side of the collet 113 and configured to contact the semiconductor chip SC.

The main body 111 may have a column shape such as a cylinder or a polygon, such as a right prism. For example, the main body 111 may be a right prism with four sides, and a vacuous path may be provided to the main body 111. The vacuous path may be connected to the heater portion 112. The main body 111 may be, as a non-limiting example, made of a material such as an aluminum oxide (Al₂O₃).

The heater portion 112 may, for example, have a rectangular plate shape. The heater portion 112 may be, as a non-limiting example, a ceramic heater including an electrical resistance heating wire. The collet 113 may be, as a non-limiting example, made of a thermally conductive material such as stainless steel, copper, aluminum, and/or the like. In at least one embodiment, the collet 113 may be configured to diffuse heat produced by the heater portion 112, thereby distributing the heat evenly across a lower side of the collet 113.

In at least one embodiment, the heater portion 112 may perform a high-temperature heating. For example, the heater portion 112 may perform a high-temperature heating function at a temperature of greater than or equal to 250° C., and/or greater than or equal to 300° C. The heater portion 112 may transfer heat to the collet 113 and the head portion 114, and may heat-pressurize the semiconductor chip SC.

The head portion 114 is installed on the lower side of the collet 113, and, in at least one embodiment, an area of an upper side of the head portion 114 may be less than an area of the lower side of the collet 113. The area and the shape of the upper side of the head portion 114 may be selected to be substantially equivalent to or greater than the area and the shape of the upper side of the semiconductor chip SC.

The substrate support 120 may be disposed below the bonding head 110, and the substrate 121 may be disposed on an upper side. The substrate support 120 may heat the substrate 121 at a relatively low temperature. For example, the substrate support 120 may be configured to heat the substrate 121 with the temperature that is lower than the heater portion 112 of the bonding head 110. The substrate support 120 may heat the substrate 121 at the temperature within a range of, e.g., 50 to 150° C., and/or a range of 50 to 100° C. The substrate support 120 may perform a low-temperature heating so that the substrate 121 may be stably bonded to the semiconductor chip SC without bending.

The substrate 121 may be, as a non-limiting example, a member such as a carrier substrate, a printed circuit board, and/or a lead frame. The bonding device according to at least one embodiment may bond the semiconductor chip in the wafer level package. When a process for bonding a semiconductor chip is performed on the wafer level, the substrate 121 may include a wafer, and the substrate 121 shown in the drawing may be considered to show the substrate 121 in the singulated single package.

The gas blower 130 is a member configured to supply gas in the direction of the substrate 121. For example, the gas blower 130 may be spaced apart from the substrate support 120, and may be spaced apart from the bonding head 110. In at least one embodiment, the gas blower 130 may surround an edge of the bonding head 110. The gas blower 130 may, for example, be connected to a gas providing pump (not illustrated), and may be configured to spray the gas provided by the pump in the direction of the substrate 121.

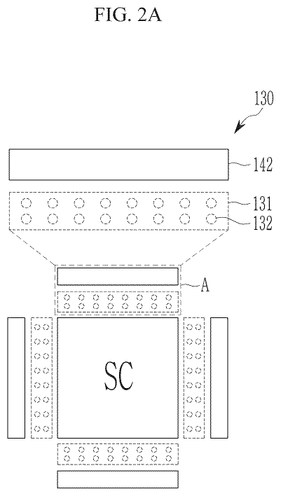

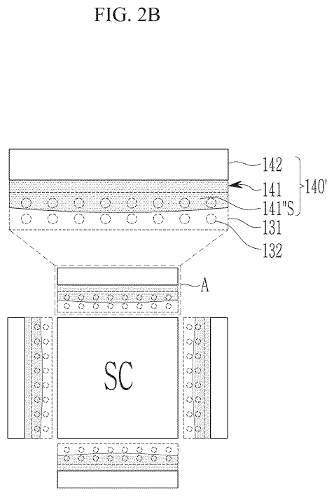

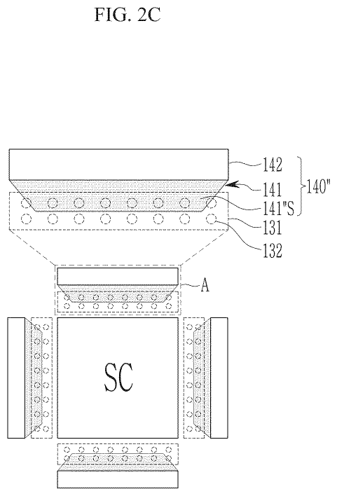

The gas blower 130 may include first to fourth spray portions 131 (see FIG. 2A) surrounding sides of the bonding head 110. The gas blower 130 may surround the side of the bonding head 110 to appropriately control spreading of the non-conductive film filet 150.

In at least one embodiment, the gas blower 130 may be inclined to have a predetermined (and/or otherwise determined) angle with respect to an upper side of the substrate support 120. For example, the gas blower 130 may be inclined with a range of 25° to 65° with respect to the upper side of the substrate support 120. As the angle of the gas blower 130 is adjusted within the above-noted range to spray gas, which has the advantages of reducing, mitigating, and/or preventing the non-conductive film filet 150 from spreading in a narrow gap, and easily spraying the gas. In at least one embodiment, the gas blower 130 is configured to form a gas wall (e.g., like a curtain) in the direction of the substrate 121 to primarily reduce, mitigate, and/or prevent the non-conductive film filet 150 from spreading.

In at least one embodiment, the gas sprayed from the gas blower 130 may be inert gas. For example, the inert gas may be like nitrogen, argon with low reactivity, and/or like.

In at least one embodiment, the gas sprayed from the gas blower 130 may be hot gas. The temperature of the gas may be given between the lowest viscosity temperature of the non-conductive film (configuring the non-conductive film filet 150) and a curing temperature of the non-conductive film. In at least one embodiment, the temperature of the gas may be 150 to 250° C.

In embodiment wherein the temperature of the gas satisfies the above-noted range, the spreading of the edge of the non-conductive film filet 150 is primarily reduced, mitigated, and/or prevented, a pre-curing is generated to control a length of the non-conductive film filet 150 in a length direction (e.g., a direction parallel to an upper surface of the substrate 121) and a length in a height direction (e.g., a direction perpendicular to the upper surface of the substrate 121), areas of non-curing (and/or less curing) are reduced, mitigated, and/or prevented, and/or the non-conductive film may be uniformly cured. In contrast, when the temperature of the gas digresses from the above-noted temperature range and is, e.g., low, it may hinder a fluent flow of the non-conductive film filet 150 (e.g., to increase defects caused by generation of voids in the edge portion of the semiconductor chip SC), and a reflow may be needed in a subsequent process because of the non-curing.

The dam member 140 is configured to limit the spreading of the non-conductive film filet 150 during the thermal compression bonding (TCB) process. The non-conductive film filet 150 may be a member for adhesion of a solder bump SD of the semiconductor chip SC, an access pad SDL, and a pad 122 of the substrate 121.

The non-conductive film filet 150 may be melted and be fluid for the thermal compression bonding process. The non-conductive film filet 150 may function as an adhesive for bonding the semiconductor chip SC to the substrate 121 and/or another semiconductor chip.

The non-conductive film filet 150 may reduce, mitigate, and/or prevent the substrate 121 from bring bent because of a difference of heat expansion coefficients between the semiconductor chip SC and the substrate 121 for the bonding process. In at least one embodiment, the non-conductive film filet 150 may, for example, include an epoxy material and./or may supplement a gap between the semiconductor chip SC and the substrate 121. In at least one embodiment, the non-conductive film filet 150 may perform an underfilling function for filling a space between the solder bump SD.

The dam member 140 may be spaced from a side of the gas blower 130, may be disposed on an outside of the gas blower 130, and/or may contact an upper side of the substrate 121 in order to limit the spreading of the non-conductive film filet 150 and to induce the gas supplied by the gas blower 130 to flow strongly and quickly in the direction of the semiconductor chip SC. The dam structure may also be referred to preventing of the non-conductive film filet 150 from spreading. The dam member 140 further contacts the substrate 121 to secondarily reduce, mitigate, and/or prevent the substrate 121 from spreading from the non-conductive film filet 150.

In at least one embodiment, the dam member 140 may be made of a material such as silicon, fluorine, and/or a compound thereof. The dam member 140 may, as a non-limiting example, be made of materials having excellent heat resistance, a sealing property, and a releasing property. As the dam member 140 is configured as described above, it is not deformed and has heat resistance when a high temperature gas is supplied. As the dam member 140 contacts the upper side of the substrate 121, it may block the flow of the non-conductive film filet 150.

In at least one embodiment, the dam member 140 may include a gas control member 141 configured to control a direction of gas, and a support portion 142 disposed on the gas control member 141 and configured to fix the gas control member 141 to the substrate 121. The support portion 142 may be connected to a transfer member (not shown). A transfer member (not shown) may be connected to the support portion 142, and after a thermal compression bonding process is performed, may be configured to separate the dam member 140 from the substrate 121.

In at least one embodiment, the operation of the device 100 may be controlled by processing circuitry, such as hardware, software, or a combination of hardware and software. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc., and/or electronic circuits including said components. For example, the device 100 may include or be connected to processing circuitry configured to implement computer-implementable instructions.

The support portion 142 may be disposed on and configured to support the gas control member 141 such that that the dam member 140 is configured to be moved in close and form a sealed contact with the substrate 121. In at least one embodiment, the support portion 142 is disposed on a side of the gas blower 130, and higher than the gas blower 130 to reduce, mitigate, and/or prevent the gas supplied by the gas blower 130 from being discharged to the outside, and to easily assist in controlling the flow and flux of gas.

In at least one embodiment, the non-conductive film filet 150 may be disposed under the corner portion of the semiconductor chip SC. The spreading of the non-conductive film filet 150 is restricted by the gas blower 130 and the dam member 140, and at the same time, a region in which the non-conductive film filet 150 is not filled under the corner of the semiconductor chip SC is reduced, mitigated, and/or prevented from occurring, and an overflow of the non-conductive film filet 150 in the middle of the semiconductor chip SC may be reduced, mitigated, and/or prevented.

Referring to FIG. 1B, regarding the cross-sectional shape of a lower structure of the dam member 140, an area thereof may increase when going downward. For example, one side of the gas control member 141 facing the semiconductor chip SC may have a slant at a predetermined angle. More specifically, the one side of the gas control member 141 facing the semiconductor chip SC may have a curve surface. The curved surface may, for example, be concave downward. As the one side of the gas control member 141 has a concave shape with a slant, the flow of gas may easily control the size and shape of the non-conductive film filet 150 and may reduce, mitigate, and/or prevent the non-conductive film filet 150 from spreading.

Referring to FIG. 1C, the one side of the gas control member 141 facing the semiconductor chip SC may be a plane inclined at a predetermined angle. As the one side is formed of a plane, a spreading of the non-conductive film filet 150 may be reduced, mitigated, and/or prevented, and an occurrence of voids in the edge portion of the semiconductor chip SC may be controlled.

FIG. 2A to FIG. 2C show top plan views of a device for bonding a semiconductor chip according to at least one embodiment of the present disclosure.

FIG. 2A shows a top plan view of a semiconductor chip bonding device 100 according to the example of FIG. 1A, FIG. 2B shows a top plan view of a semiconductor chip bonding device 100 according to the example of FIG. 1B, and FIG. 2C shows a top plan view of a semiconductor chip bonding device 100 according to the example of FIG. 1C. In at least one embodiment, the first to fourth spray portions 131 may have a bar shape including a long side and a short side. A plurality of blowing holes 132 may be formed on lower surfaces of the first to fourth spray portion 131, and gas may be sprayed through the blowing holes 132.

In at least one embodiment, the blowing holes 132 may be arranged in a lattice form of rows and columns and/or in a honeycomb form. In at least one embodiment, the shape of the blowing hole 132 may have a circular, elliptical, quadrangular, or polygonal shape. However, the number, disposition, and shape of the blowing holes 132 are non-limiting examples and are not limited thereto.

Referring to an enlarged region A of FIG. 2A, the gas control member 141 and the support portion 142 of the dam member 140 may have the same area on a plane, and the support portion 142 may be disposed on the gas control member 141.

Referring to FIG. 2B and FIG. 2C, when the dam member 140 is viewed from the top to the bottom, areas of the gas control members 141′ and 141″ and the support portions 142′ and 142″ in a plan view may be different. In at least one embodiment, a gap between the non-conductive film filet 150 and the gas control member 141 may be gradually narrowed according to a movement direction of gas supplied from the gas blower 130.

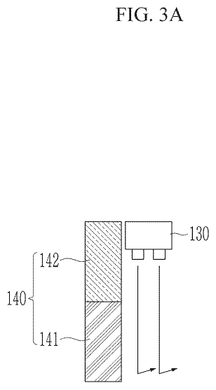

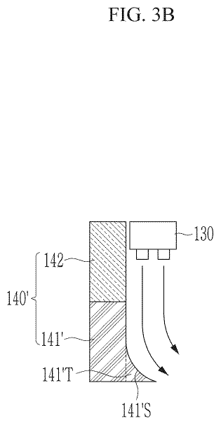

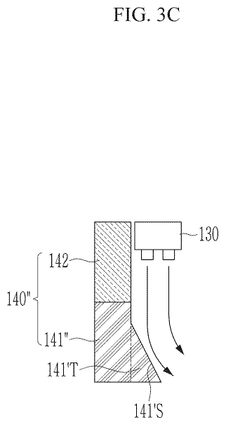

In at least one embodiment, the gas control members 141′ and 141″ may have protrusions 141′T and 141″T in FIG. 3B and FIG. 3C. Specifically, the protrusions 141′T and 141″T may have slant portions 141'S and 141″S inclined with an angle with respect to the substrate 121.

Referring to an enlarged region A of FIG. 2B, the slant portion 141'S of the protrusion 141′T may have a curved shape. Specifically, the shape of the slant portion 141'S in a plan view may have a streamline shape. More specifically, the streamline shape of the slant portion 141'S may have a convex shape in the direction in which the semiconductor chip SC is disposed.

Referring to an enlarged region A of FIG. 2C, the slant portion 141″S of the protrusion 141″T may have a trapezoidal shape. Specifically, the slant portion 141″S in a plan view may have a trapezoidal shape. In at least one embodiment, the area of the slant portion 141″S in a plan view may gradually decrease when going to a direction in which the semiconductor chip SC is disposed from a direction in which the support portion 142″ is disposed.

As the slant portions 141'S and 140″S have a streamline shape or trapezoidal shape in a plan view, the strength of the gas supplied from the gas blower 130 is increased to easily control the size of the insulating filet film 150; block the spreading of the insulating filet film 150; reduce, mitigate, and/or prevent a non-curing, maintain a uniform curing; and/or reduce, mitigate, and/or prevent voids from being generated in the edge of semiconductor chip SC.

Referring to an enlarged region A of FIG. 2B and FIG. 2C, the slant portions 141'S and 140″S may be expanded so that some regions thereof may be overlapped and disposed under the gas blower 130. As the slant portions 141'S and 140″S are overlapped and disposed below the gas blower 130, the direction of the gas supplied from the gas blower 130 is controlled to be the direction of the non-conductive film filet 150, and the flow intensity is increased to easily control the size of the non-conductive filet film 150, block the spreading of the non-conductive filet film 150, and reduce, mitigate, and/or prevent an un-curing. In addition, it is possible to maintain a uniform curing and reduce, mitigate, and/or prevent voids from occurring at the edge portion of the semiconductor chip SC.

FIG. 3A to FIG. 3C show schematic diagrams of movement of gas by a dam member 140 of a device 100 for bonding a semiconductor chip according to at least one embodiment of the present disclosure.

FIG. 3A shows a movement of gas caused by a dam member 140 of a semiconductor chip bonding device 100 of FIG. 1A. As the dam member 140 is disposed outside the gas blower 130, the gas supplied from the gas blower 130 moves in a direction that is opposite to the direction in which the dam member 140 is disposed. The spread of the non-conductive film filet 150 is primarily reduced, mitigated, and/or prevented by the gas supplied from the gas blower 130, and the dam member 140 is disposed outside the gas blower 130 to secondarily reduce, mitigate, and/or prevent the non-conductive film filet 150 from spreading and to reduce, mitigate, and/or prevent the gas supplied from the gas blower 130 from being sprayed in a direction that is opposite to the non-conductive film filet 150.

FIG. 3B shows a movement of gas caused by a dam member 140′ of a semiconductor chip bonding device 100′ of FIG. 1B. In at least one embodiment, an area of the gas control member 141 including the protrusion 141′T in a cross-sectional view may gradually increase when approaching to the substrate 121 on the support portion 142′. For example, the gas control member 141′ may include a protrusion 141′T protruding in a direction in which gas is supplied.

A cross-sectional area of the protrusion 141′T may gradually increase as one side of the gas supplying direction goes downward. As one side of the protrusion 141′T gradually increases downward, the flow of the gas may be controlled in the direction in which the semiconductor chip SC is bonded.

In at least one embodiment, the slant portion 141'S included in the protrusion 141′T may have a curve in a cross-sectional view. As the slant portion 141'S has a curved line in cross-section, the flow of gas supplied from the gas blower 130 is the curved line. The flow of the changed gas is directed to the member of the non-conductive film filet 150, and the gas reaches the member of the non-conductive film filet 150 quickly and strongly, thereby reducing, mitigating, and/or preventing the non-conductive film filet 150 from spreading.

FIG. 3C shows a movement of gas caused by a dam member 140″ of a semiconductor chip bonding device 100″ of FIG. 1C. In at least one embodiment, the slant portion 141″S may have a straight line in a cross-sectional view. Specifically, the slant portion 141″S may have a straight line in a cross-sectional view, and the cross-section of the protrusion 141″T may have a triangular shape. The triangle shape is disposed so that the cross-section may increase in the gas supplying direction. Accordingly, the gas may move along a hypotenuse of the triangular shape.

The flow of the gas supplied from the gas blower 130 is changed along a curved line of the slant portion 141″S in a cross-sectional view. The flow of the changed gas is directed to the member of the non-conductive film filet 150, and the gas reaches the member of the non-conductive film filet 150 quickly and strongly, thereby reducing, mitigating, and/or preventing the non-conductive film filet 150 from spreading.

In at least one embodiment, the slant portions 141'S and 141″S of the gas control members 141′ and 141″ may have a slant at a predetermined angle with respect to the substrate 121. For example, the predetermined angle may be within a range of 5° to 85°, 10 to 70°, and/or 15 to 60°. The slant portions 141'S and 141″S may include a slant having an angle in the aforementioned ranges to control the flow of gas and reduce, mitigate, and/or prevent the non-conductive film filet 150 from spreading.

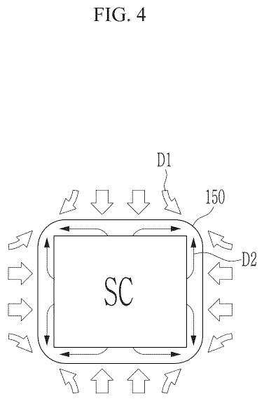

FIG. 4 shows a gas supplying direction D1 and a flowing direction D2 of a non-conductive film filet according to at least one embodiment of the present disclosure.

Referring to FIG. 4, regarding the gas supplying direction D1, the gas may be supplied by the dam member 140 toward the corner from the center of the non-conductive film filet 150 disposed below the semiconductor chip SC. As the gas supplying direction D1 proceeds to the corner from the center of the non-conductive film filet 150, an excessive spreading in the flowing direction D2 of the non-conductive film filet 150 is reduce, mitigate, and/or prevented in the middle region, and voids are reduced, mitigated, and/or prevented from being generated in the in the edge region when the flowing direction D2 grows to the edge region. Therefore, the non-conductive film filet 150 may be disposed in a uniform form along the edge of the semiconductor chip SC in a plan view.

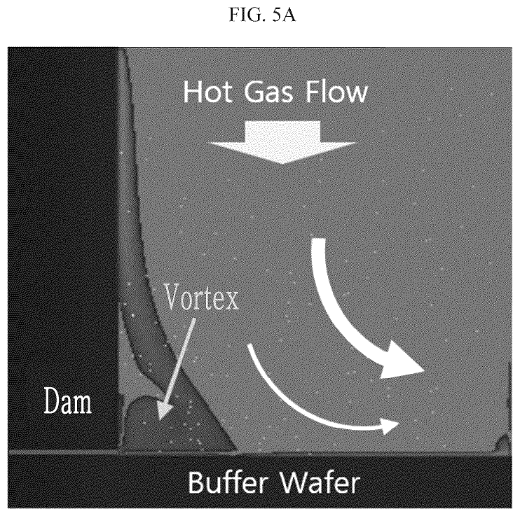

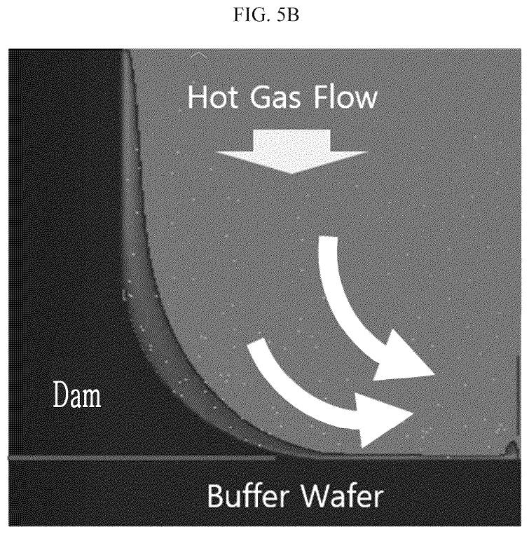

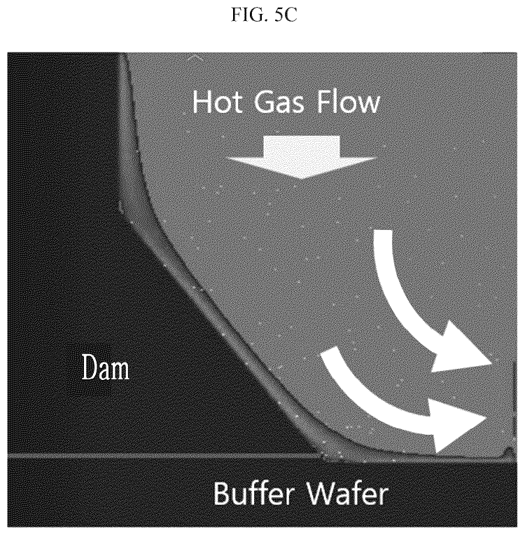

FIG. 5A to FIG. 5C show a simulation according to influences of a cross-section of a dam member 140 according to some embodiments of the present disclosure.

FIG. 5A shows a simulation result according to a cross-section of a dam member 140 of FIG. 3A, FIG. 5B shows a simulation result according to a cross-section of a dam member 140′ of FIG. 3B, and FIG. 5C shows a simulation result according to a cross-section of a dam member 140″ of FIG. 3C. In the case of the flux of the supplied gas, it is found that FIG. 5B is similar to FIG. 5C, and FIG. 5B and FIG. 5C are faster than FIG. 5A.

For example, referring to FIG. 5A to FIG. 5C, gas is supplied in the direction where the substrate 121 is disposed, and part of the flow of the supplied gas is disturbed and swirls in the direction that is opposite to a main current, thereby forming a vortex. It is found that the vortex is prominently generated in 5A, and the less vortex is generated in FIG. 5B and FIG. 5C than in FIG. 5A. The flux and the vortex of gas are influenced by the shape of the gas control member 141 among the dam member 140 in a cross-sectional view, and it is found that the effect is improved when the shape in a cross-sectional view is slanted at a predetermined angle from top to bottom.

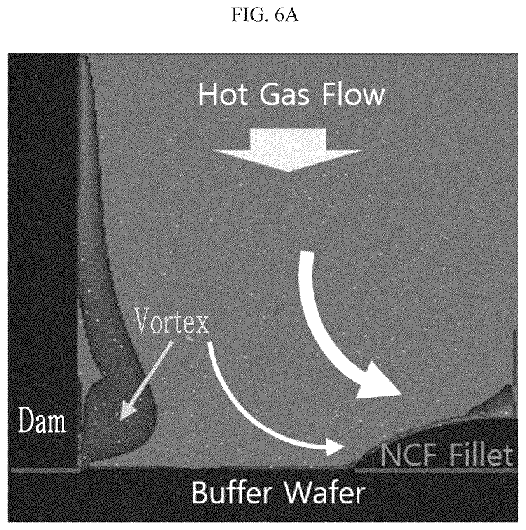

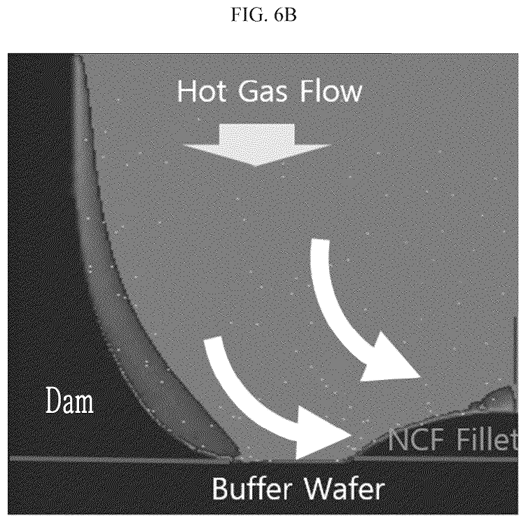

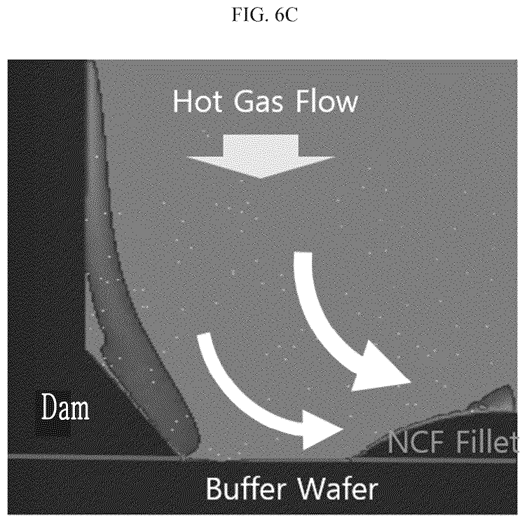

FIG. 6A to FIG. 6C show a simulation according to influences of cross-sections of dam members 140, 140′, and 140″ and a non-conductive film filet according to at least one embodiment of the present disclosure.

FIG. 6A shows a simulation result for confirming influences of a non-conductive film filet 150 according to a cross-section of a dam member 140 of FIG. 5A, FIG. 6B shows a simulation result for confirming influences of a non-conductive film filet 150 according to a cross-section of a dam member 140′ of FIG. 5B, and FIG. 6C shows a simulation result for confirming influences of a non-conductive film filet 150 according to a cross-section of a dam member 140″ of FIG. 5C.

Referring to FIG. 6A to FIG. 6C, when gas is supplied while the non-conductive film filet 150 is disposed, it is found that the flux of gas is faster in order of FIG. 6B, FIGS. 6C, and 6A, and the vortex generated from gas is great in order of FIG. 6A, FIG. 6C, and FIG. 6B. As such, it is found that the flux and the generation of vortex are different according to degrees of inclination and shapes of one sides of the dam members 140, 140′, and 140″.

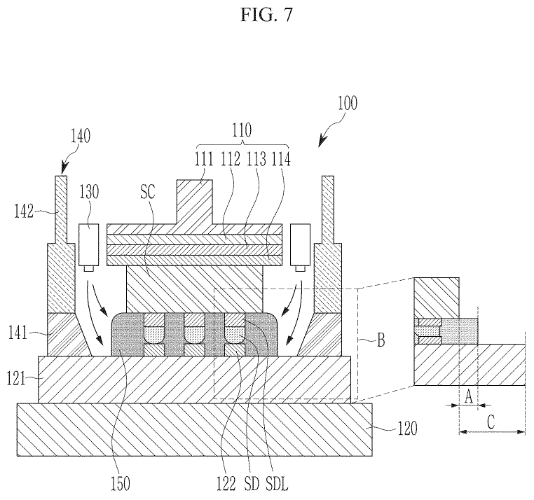

FIG. 7 shows a relationship between a non-conductive film filet 150 and a substrate 121 according to at least one embodiment of the present disclosure.

FIG. 7 shows a process for generating a non-conductive film filet 150. The right side of FIG. 7 shows an enlarged region B after a thermal compression bonding process is performed and the dam member 140 removed. When the B region after the thermal compression bonding process is performed is enlarged and examined, a relational expression between the substrate 121 and the non-conductive film filet 150 may satisfy Equation 1.

$$5 \% \leq A / C \leq 50 \% \qquad < Equation 1 >$$

wherein, A is an exposed length of the non-conductive film filet 150, and C is a length of the substrate 121 in the direction in which the non-conductive film filet 150 grows with respect to a sidewall of the semiconductor chip SC).

By satisfying Equation 1, the non-conductive film filet 150 can grow in all directions. When Equation 1 is out of a lower limit value, similar to conventional art, voids are generated at the corner of the semiconductor chip SC, and when Equation 1 is out of the upper limit value, a semiconductor chip packaging may not be refined.

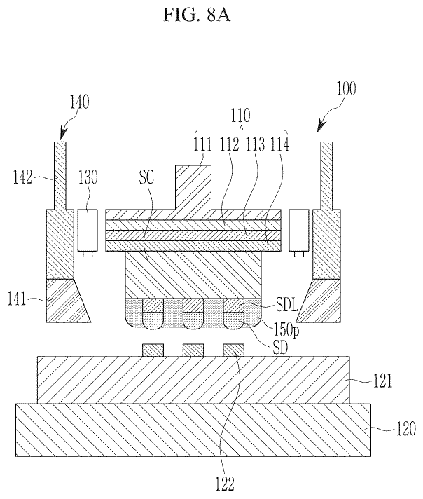

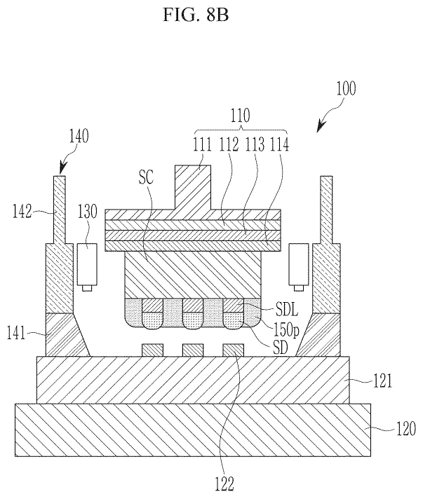

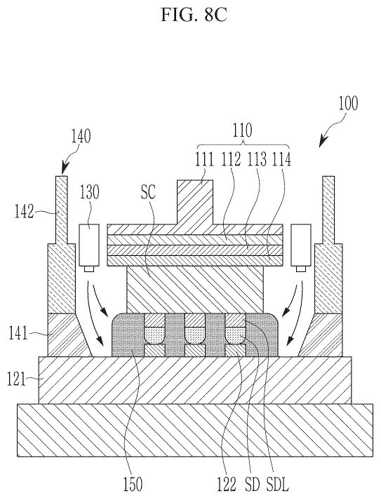

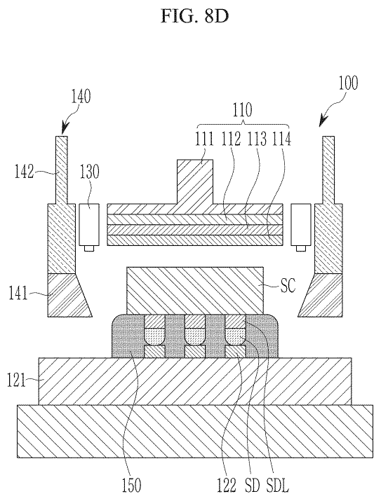

FIG. 8A to FIG. 8D show a method for bonding a semiconductor chip using a device 100 for bonding a semiconductor chip according to at least one embodiment of the present disclosure.

Referring to FIG. 8A to FIG. 8D, the method for bonding a semiconductor chip may include: allowing a bonding head 110 to dispose a semiconductor chip SC (with one side on which a non-conductive film 150p is disposed) on the substrate 121; surrounding the semiconductor chip SC with the dam member 140, the dam member 140 spaced apart from an edge of the semiconductor chip SC and allowing the dam member 140 to contact an upper side of the substrate 121; allowing a bonding head 110 to provide heat and pressure to the semiconductor chip SC to perform a bonding between the semiconductor chip SC and the substrate 121; and allowing a gas blower 130 to spray gas along at least one side of the dam member 140 between the semiconductor chip SC and the dam member 140.

Referring to FIG. 8A, the allowing of a bonding head 110 to dispose a semiconductor chip SC on the substrate 121 may include allowing the bonding head 110 to absorb the semiconductor chip SC and arranging the semiconductor chip SC on the substrate 121. The bonding head 110 or the substrate support 120 may be moved so that the bonding head 110 may absorb the semiconductor chip SC and the absorbed semiconductor chip SC may be disposed on the substrate 121. For example, in at least one embodiment, the bonding head 110 may include, at least one of a vacuum chuck, an electromagnetic chuck, a mechanical chuck, and/or the like.

The semiconductor chip SC may include a die, a wire layer, a through-silicon via (TSV), and access pad, an adhesive layer, and/or the like. The wire layer and the access pad SDL may be disposed on at least one side of the die. The wire layer may include a wire pattern and an insulation layer. The TSV may pass through the die and may be electrically connected to the wire pattern of the wire layer and the access pad SDL. In at least one embodiment, regarding the semiconductor chip SC, a solder bump SD may be disposed under and/or on the access pad SDL.

The solder bump SD may be configured to form an electrical connection between the TSV and circuit structures formed in the die. The semiconductor chip SC may cover members such as the solder bump SD and the access pad SDL with the non-conductive film 150p which may be an adhesive layer.

Referring to FIG. 8B, the dam member 140 may surround the edge of the semiconductor chip SC may be spaced apart from the edge of the semiconductor chip SC by a predetermined (or otherwise determined) interval and may contact the upper side of the substrate 121. The dam member 140 may contact the upper side of the substrate 121 before growing the non-conductive film 150p to provide a space for the non-conductive film 150p to grow in a closed and sealed region. As the non-conductive film 150p grows in a closed and sealed region, as described above, it is possible to primarily reduce, mitigate, and/or prevent the non-conductive film 150p from overflowing and spreading.

Referring to FIG. 8C, the performing of a bonding by providing heat and pressure to the semiconductor chip SC by the bonding head 110 may be performed by a thermal compression bonding (TCB) process. Through the thermal compression bonding process, the non-conductive film may be melted to secure fluidity. The non-conductive film may function as an adhesive for bonding the semiconductor chip SC to the substrate 121 or other semiconductor chips.

In the performing of a bonding (e.g., by providing heat and pressure to the semiconductor chip SC by the bonding head 110), the non-conductive film may perform an underfill function (e.g., filling a space between the solder bumps SD). The solder bump SD may be bonded during the thermal compression bonding process, and the temperature at which the solder bump SD is bonded may be higher than the melting point of the non-conductive film. For example, the temperature at which the solder bump SD is bonded may be greater than or equal to 150° C.

In at least one embodiment, the performing of a bonding by providing heat and pressure to the semiconductor chip SC by the bonding head 110 may further include preliminary heating the semiconductor chip SC to a pre-bonding temperature. The preliminary heating may be performed by the substrate support 120 performing a low temperature heating. For example, the substrate support 120 may heat the substrate 121 to a temperature in the range of 50 to 150° C., and/or 50 to 100° C.

The substrate 121 may be disposed on the substrate support 120 performing a low temperature heating, and may apply heat to the non-conductive film 150p disposed on the substrate 121. By including the pre-heating, adhesion and fluidity may be obtained by the non-conductive film of the semiconductor chip SC thereby enabling control during a pre-bonding state.

In the allowing of a gas blower 130 to spray gas along one side of the dam member 140 between the semiconductor chip SC and the dam member 140, the gas may be sprayed toward the non-conductive film 150p disposed between the semiconductor chip SC and the substrate 121. The gas may mean hot gas, and a detailed description thereof is provided above in reference to FIG. 1A. By spraying gas along one side of the dam member 140, the non-conductive film filet 150 having a target height and size is generated, e.g., by growing the non-conductive film 150p.

In at least one embodiment, in the disposing of the gas blower 130 among the dam member 140, which is disposed apart from the side of the bonding head 110 and is disposed in contact with the substrate 121, the bonding head 110, and the dam member 140, the dam member 140 has a slant portion to control the flux and the direction of gas. A detailed description of the dam member 140 may refer to the content described with reference to FIG. 1A to FIG. 7 to the extent that the examples are not contradictory.

In at least one embodiment, the spraying of gas from the gas blower 130 along one side of the dam member 140 may include reducing, mitigating, and/or preventing an edge of the non-conductive film from being exposed and pre-curing the non-conductive film. The pre-curing may be performed when the temperature of the gas supplied from the gas blower 130 is within a range of 150° C. to 250° C. The spreading of the non-conductive film may be primarily and secondarily reduced, mitigated, and/or prevented by the gas supplied from the gas blower 130 and the dam member 140, and the non-conductive film may expand to the center region with respect to the semiconductor chip, reducing, mitigating, and/or preventing the voids from being generated in the edge region.

In at least one embodiment, in the disposing of the gas blower 130 among the dam member 140, which is disposed apart from the side of the bonding head 110 and is disposed in contact with the substrate 121, the bonding head 110, and the dam member 140, the bonding head 110 and the dam member 140 may be integrally formed. The bonding head 110 and the dam member 140 may be integrally formed and controlled by a controller. As the bonding head 110 and the dam member 140 are integrally formed and controlled, it is easy to control the size of the non-conductive film filet 150, which is a merit.

Referring to FIG. 8D, when the semiconductor chip bonding process is completed, the bonding head 110, the gas blower 130, and the dam member 140 may be separated from the substrate 121 or the semiconductor chip SC.

FIG. 8A to FIG. 8D show the process for forming a semiconductor chip SC, but other semiconductor chips may be bonded on the substrate around the semiconductor chip SC, and a plurality of semiconductor chip SCs may be stacked instead of one semiconductor chip SC.

While this disclosure has been described in connection with what is presently considered to be practical embodiments, it is to be understood that the disclosure is not limited to the disclosed embodiments and/or the examples, but, on the contrary, is intended to cover various modifications and equivalent arrangements included within the spirit and scope of the appended claims. Therefore, the embodiments and/or the examples described above are only examples and should not be construed as being limitative in any respects.

What is claimed is:

1. A device configured to bond a semiconductor chip on a substrate, the device comprising:
a bonding head configured to be on the semiconductor chip;
a substrate support configured to support the substrate;
a dam member configured to surround an edge of the bonding head and to contact an upper side of the substrate; and
a gas blower configured to be spaced apart from and over the substrate support, to be between the bonding head and the dam member, and to supply gas towards the substrate.

2. The device of claim 1, wherein the dam member includes
a gas control member configured to contact the upper side of the substrate and to control a direction of the gas, and
a support portion above the gas control member, the support portion configured to fix the gas control member to the substrate.

3. The device of claim 2, wherein
one side of the gas control member facing the semiconductor chip has a slant, and
the one side includes a curve or a plane.

4. The device of claim 2, wherein an area of the gas control member in a cross-sectional view gradually increases when approaching to the substrate.

5. The device of claim 2, wherein
the gas control member includes a protrusion, and
the protrusion has a slant portion having an angle with respect to the substrate.

6. The device of claim 5, wherein the slant portion has a curved shape or a trapezoidal shape in a plan view.

7. The device of claim 5, wherein the slant portion has at least one of a straight line or a curve in a cross-sectional view.

8. The device of claim 1, wherein the dam member comprises at least one of silicon, fluorine, or a compound thereof.

9. The device of claim 1, wherein
the bonding head includes a heater portion, and
the heater portion is configured to heat the bonding head to a temperature of 250° C. or more.

10. The device of claim 1, wherein a temperature of the gas is in a range of 150° C. to 250° C.

11. The device of claim 1, wherein
the substrate support is configured to heat the substrate to a temperature in a range of 50° C. to 150° C.

12. The device of claim 1, wherein the gas blower is configured to supply an inert gas.

13. The device of claim 1, wherein
the gas blower includes first to fourth spray portions surrounding the bonding head, and
the first to fourth spray portions have a bar shape including a long side and a short side.

14. The device of claim 13, wherein
the first to fourth portions are configured with a plurality of blowing holes, and
the blowing holes are in a lattice.

15. A device configured to bond a semiconductor chip on a substrate and to limit a non-conductive film filet from spreading, the device comprising:
a bonding head configured to heat-pressurize the semiconductor chip, the bonding head including a heater portion, a collet on a lower side of the heater portion, and a head portion on a lower side of the collet and configured to contact the semiconductor chip;
a substrate support configured to support the substrate and to heat the substrate to a temperature range lower than a temperature range of the heater portion;
a dam member including a gas control member and a support portion, the gas control member configured to surround the bonding head, to contact an upper side of the substrate, and including a slant portion with an angle with respect to the substrate, and the support portion on the gas control member and configured to fix the gas control member to the substrate; and
a gas blower configured to be spaced apart from and over the substrate support, to be between the bonding head and the dam member, and to supply gas of 150° C. or more towards the substrate.

16. The device of claim 15, wherein the temperature range of the gas is 150 to 250° C.

17. The device of claim 15, wherein the heater portion is configured to heat the head portion to 250° C. or more.

18. The device of claim 15, wherein the substrate support is configured to heat the substrate to within a range of 50° C. to 150° C.

19. A method for bonding a semiconductor chip comprising:
using a bonding head to position a semiconductor chip on a substrate such that a non-conductive film of the semiconductor chip is between the semiconductor chip and the substrate;
positioning a dam member to surround the semiconductor chip such that dam member is spaced apart from an edge of the semiconductor chip and contacts an upper side of the substrate;
bonding the semiconductor chip to the substrate by providing heat and pressure to the semiconductor chip; and
spraying gas along at least one side of the dam member, the at least one side of the dam member being between the semiconductor chip and the dam member.

20. The method of claim 19, wherein
the spraying of gas includes pre-curing the non-conductive film.
